(19) United States
(12) Patent Application Publication
(10) Pub. No.: US 2012/0240843 A1
(43) Pub. Date: Sep. 27, 2012

(54) On Demand Thin Silicon

(76) Inventor: Francisco Machuca, Pleasant Hill, CA (US)

(21) Appl. No.: 13/069,115

(22) Filed: Mar. 22, 2011

(51) Int. Cl. C30B 13/24; C30B 13/16

(52) U.S. Cl. 117/39; 117/43

(57) ABSTRACT

A method and system is disclosed for making ultra thin wafer(s) or thin film(s) of c-Si on demand. One aspect of certain embodiments includes using a planar seed or crystal template in combination with shaped scanning heat sources to produce an intermediate seed or secondary crystal template, and finally producing an ultra thin wafer or thin film with a single crystal structure over an arbitrary area and film thickness starting from an initial low quality Si coating.

### TECHNICAL FIELD

The disclosed embodiments relate generally to making thin film crystalline silicon. More particularly, the disclosed embodiments relate to methods and systems for making thin film crystalline silicon through epitaxial growth of planar thin lamella seeds on demand.

### BACKGROUND

Previous methods for achieving c-Si, also known as mono silicon; include, forming boule's or ingots of single crystal pulled from a melt using a small 3-D seed of single crystal silicon (art practiced in CZ or Float zone methods for the past 50 years). Variants exist for full cylindrical boule growth, or casting methods involving formation of blocks of Si, and as well as ribbons of silicon pulled through specialized dies to approximate thin films through an extrusion process. Second, there is a primary manner of re-crystallizing films of lower crystal quality of Si (amorphous, or poly-Si) by using high intensify beams of charged particles or laser light, or even bright heat lamps, sometimes referred to as “zone melt re-crystallization” (“ZMR”).

Old methods target production of electronic grade (EG) and solar grade (SG) waters which are produced using wasteful sawing approaches. A large fraction of the high quality EG & SG boule or cast block is turned into dust and is known as Kerf loss. In addition, the wafers today tend to have 200 micron thickness (1 micron is 1×10⁻⁶ meter), leading to inefficient use of the majority of the substrate for solar cell design (a single junction solar cell requires between 30 μm to 50 μm for efficient operation) as well as various devices used for logic and memory circuits. And as technology drivers require thinner wafers, sawing wafers becomes impractical.

The ribbon technology suffers from excessive point defect densities, contamination from unwanted metal impurities from the dies used in the sheet pulling process, and uneven thickness and sheet resistance across the ribbon. In addition, standard re-crystallization using ZMR is limited to small areas targeting the improvement of silicon on the wafer level with typical areas of 156 mm×156 mm (1.0 mm=1×10⁻³ meters) and has not been demonstrated on large footprint areas (greater than 0.5 m×0.5 m). Moreover, the old re-crystallization techniques practicing standard ZMR in general preclude the use of glass due to the typical limitations of softening point temperatures of common glasses in the range of 600° C. +/−150° C. temperature. Last, prior re-crystallization methods do not include the planar seeding methodology as described herein, necessarily limiting existing standard ZMR to grain sizes of 10 microns to 1.0 mm in range, and MCL's <10 micro second,, characteristic of large point defects densities and/or metal impurities at grain boundaries.

### BRIEF DESCRIPTION OF THE DRAWINGS

For a better understanding of the aforementioned aspects of the invention as well as additional aspects and embodiments thereof, reference should be made to the description of embodiments below, in conjunction with the following drawings in which like reference numerals refer to corresponding parts throughout the figures.

FIG. 1A is a block diagram illustrating a seeding carrier with a crystal seed below the surface of the substrate, according to certain embodiments of the invention.

FIG. 1B is a block diagram illustrating a seeding carrier with a crystal seed reaching above the surface of the substrate, according to certain embodiments of the invention.

FIG. 2 is a block diagram illustrating a seeding carrier with a crystal seed embedded in the substrate and a low quality crystal silicon coating or over layer, according to certain embodiments of the invention.

FIG. 3A is a block diagram illustrating a seeding carrier in a first source scan and intermediate seed formation, according to certain embodiments of the invention.

FIG. 3B is a block diagram illustrating a seeding carrier in a subsequent source scan using the intermediate seed, according to certain embodiments of the invention.

FIG. 4 is a block diagram illustrating a CMOS compatible process to create a seeding carrier, according to certain embodiments of the invention.

FIG. 5 is a block diagram illustrating a laser line melt zone formation and seeding on a seeding carrier, according to certain embodiments of the invention.

FIG. 6 is a block diagram illustrating the completion of the CMOS compatible process to create a seeding carrier, according to certain embodiments of the invention.

FIG. 7 is a block diagram illustrating a glass panel as a seeding carrier, according to certain embodiments of the invention.

### DESCRIPTION OF EMBODIMENTS

Methods, systems and other aspects of the invention are described. Reference will be made to certain embodiments of the invention, examples of which are illustrated in the accompanying drawings. While the invention will be described in conjunction with the embodiments, it will be understood that it is not intended to limit the invention to these particular embodiments alone. On the contrary, the invention is intended to cover alternatives, modifications and equivalents that are within the spirit and scope of the invention. The specification and drawings are, accordingly, to be regarded in an illustrative rather than a restrictive sense.

Moreover, in the following description, numerous specific details are set forth to provide a thorough understanding of the present invention. However, it will be apparent to one of ordinary skill in the art that the invention may be practiced without these particular details. In other instances, methods, procedures, components, and networks that are well known to those of ordinary skill in the art are not described in detail to avoid obscuring aspects of the present invention.

According to certain embodiments, planar thin lamella seeds are used in combination with shaped scanning heat sources to produce single crystalline silicon of arbitrary area arid film thickness in a new method called 2D CZ ZMR.

According to certain embodiments, a method and apparatus to push a single crystal planar silicon (Si) seed vertically and horizontally in one or more directions to re-crystallize a larger over layer or in expensive coating of silicon of arbitrary thickness and arbitrary overall lateral dimensions is used to produce single crystal silicon of arbitrary area and film thickness. Of special interest in practicing this art is to create single crystal self supported substrates, and Thin Films (TF) of crystalline silicon (c-Si) on glass or on entirely foreign substrates of a non-silicon composition. Films of c-Si, either self supporting or on high temperature substrates are of particular interest in the fields of: low cost logic circuits such as those required by RFID applications, flexible circuits for memory and logic circuit applications, and for highly efficient solar cells as characterized by minority carrier lifetimes (MCL's) of >30 microseconds in either a large footprint solar panel form factor or as a direct “drop-in” replacement for standard sawn wafers leading to low cost solar electricity.

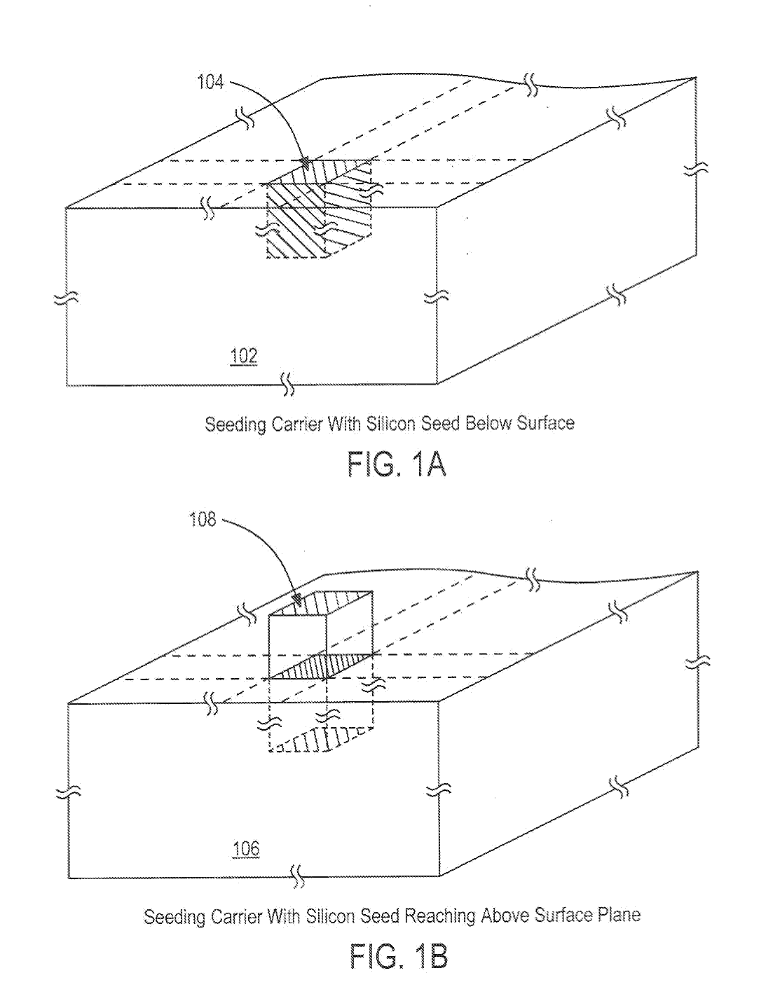

According to certain embodiments, a planar seed is a single crystal grain of silicon and that is embedded or adhered to a native or non-native substrate. A native substrate is one that is silicon in composition of any grade including metallurgical, solar grade, upgraded of any kind, or high quality electronic grade produced in any standard fashion. Secondly, the definition of native can include alloys and solid solution mixtures of silicon containing compounds. For example, silicon containing compounds include but are not limited to, silicon carbide, silicon dioxide, silicon nitride, silicon oxynitrides, silicon aluminum oxynitrides, silicon germanium, high temperature silicate glasses, and many ceramics such as mullite. An example of a non-native substrate is any foreign material or solid composition not containing silicon. FIGS. 1A, 1B demonstrate the application of a seed embedded or adhered to a native or non-native substrate. FIG. 1A is a block diagram illustrating a seeding carrier with a crystal seed below the surface of the substrate, according to certain embodiments of the invention. In FIG. 1A, the case of a subsurface seed (104) in substrate is shown. The substrate (102) shows the seed (104) as a Si rich grain or inclusion.

FIG. 1B is a block diagram illustrating a seeding carrier with a crystal seed reaching above the surface of the substrate, according to certain embodiments of the invention. FIG. 1B, shows the case of a super surface seed (108) placed above and in direct contact with the surface of substrate (106).

FIG. 1B depicts a step or extension of the substrate vertically in the form of the seed (108) in a mesa-like plateau. As described herein, in both cases where the substrate is native or non-native, the seed is referred to as a planar seed and the planar seed in combination with a substrate (102 & 104 or 106 & 108) is referred to as the seeding carrier.

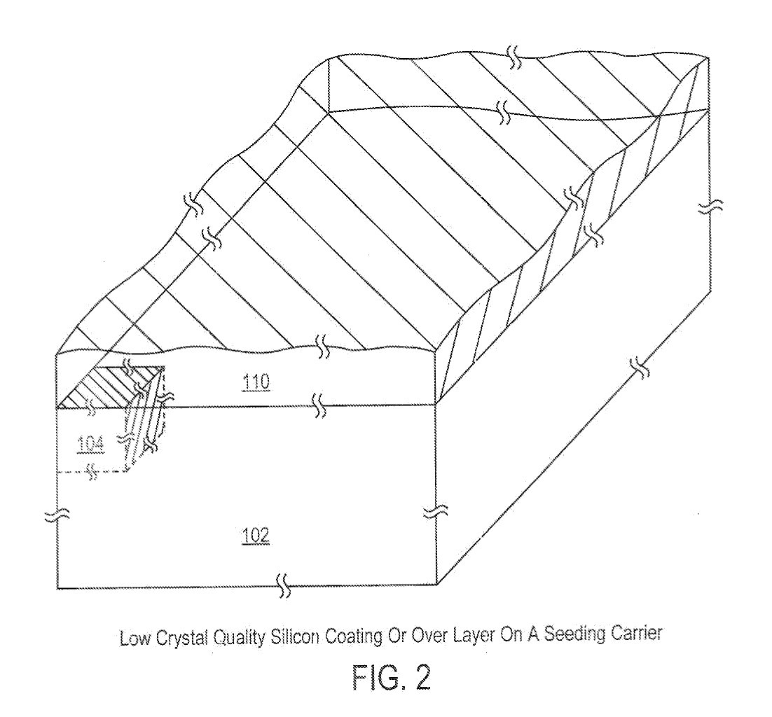

Deposition of low quality crystal Si can occur in various ways onto a high temperature seeding carrier carrying a planar silicon seed. The deposition method may include, but is not limited to, gas phase, plasma phase, liquid phase, or simple particle absorption. Deposition techniques include: physical vapor deposition, low pressure chemical vapor deposition (CVD), atmospheric pressure CVD, inject printing of colloids or inks using a silicon precursor, electrochemical plating using a chemical precursor of silicon, laser induced desorption techniques of silicon containing molecules, Si inductive or DC plasma torches with axial injected particles or liquids, or electro-statically charging and accelerating Si particles or powders using Corona discharge. The resulting layer of silicon is characterized by low quality crystal in lateral extent and in its depth profile. FIG. 2 is a block diagram illustrating a seeding carrier with a crystal seed (104) embedded in the substrate (102) and a low quality crystal silicon coating or over layer, according to certain embodiments of the invention. The poor crystal quality extends from amorphous to micro, crystalline or poly crystalline and is referred to as a Si over layer (110) in FIG. 2. Thickness of over layer (110) can be thin typically in the range of 1.0 micron to 50 microns, or thick typically >100 microns. Plasma torches have been well documented in patents such as U.S. Pat. No. 4,818,916, & U.S. Pat. No. 4,766,287 from PerkinElmer, and U520090209093 Al by Dow Corning.

After uniformly coating the high temperature carrier containing a silicon seed, a shaped energy or heat source (also referred to as “source”) is scanned or passed over the seeding carrier. Scanning can be achieved by holding the source fixed and moving the substrate linearly or rotationally. Or alternatively, the source can be moved over the substrate in similar fashion, or both source and substrate can be moved in conjunction to achieve moving the energy deposited by the source over the substrate to a multitude of locations. Motion is either continuous or stepped and determined by closed loop control of the silicon over layer properties during the melting and re-crystallization process steps. For example, a closed loop programmed logic controller can be used to monitor the process properties to set source, scan speed. Such process properties include, but is not limited to, melt condition such as temperature, optical reflectivity from the molten over layer surface, and crystal quality of the newly re-crystallized over layer of Si as determined by a minority carrier lifetime measurement in situ. The shape of the source can be a thin line, rectangular block, circle, arrow head, crescent moon, or arbitrary polygon with sufficient energy density to bring the Si over layer beyond its melting point of 1420C, during Which lime the seeding carrier remains solid. The source may be, but not limited to, focused or guided radiation of charged particles or light, visible or non-visible, or radioactive filaments such as linear rods or line heaters, or simply pulsed electro-magnetic (E&M) energy waves in regions of the electromagnetic spectrum not visible to the eye. Thus, the energy source can include light beams, or hot wire(s), or focused lamp(s), or fiber guided laser(s), or optically focused laser(s) in visible or non-visible wavelengths of the electromagnetic spectrum, focus charged particles including ions and electron beam(s), or pulsed electromagnetic radiation produced by waveguides and antennae. In the case of scanning laser light, the frequency of operation may be continuous wave or pulsed light down to the femto second time scales. The guiding or focusing of particles or light can be done by electromagnetic tenses in case of charged electrons or ions, conventional light optics for lasers and lamps (including optical lenses, fibers, gratings, etalons, liquid light guides, and mirrors), and waveguides and antennae for E&M pulses.

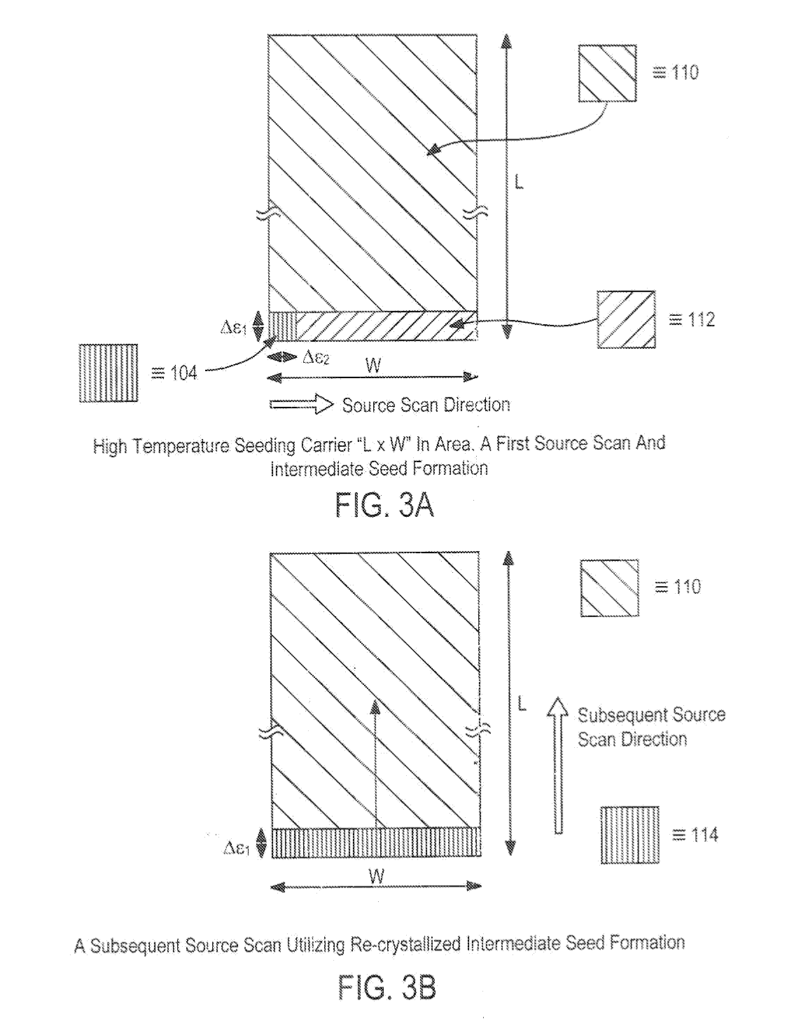

FIGS. 3A, 3B demonstrate the conversion of the initial seed into an intermediate seed in a bird's eye view drawing during the melting and re-crystallization process. FIGS. 3A, 3B illustrate the 2D CZ ZMR melt, and re-crystallization strategy for arbitrarily large work piece (114) of size “L” by “W”. FIG. 3A shows a first scan and the creation of an intermediate seed (112) of size “Δε₁” by “W” onto the Si over layer (110) using seed (104) of size “Δε₁” by “Δε₂”. FIG. 3B shows a second scan and the movement of the intermediate seed (112) across the entirety of the work piece (114) along the “L” direction. Firstly, scanning along a first direction is shown in FIG. 3A and followed by a second direction scan depicted in FIG. 3B. The initial planar seed (104) in the seeding carrier of dimension Δε₁ by Δε₂ is utilized to crystallize a partitioned region drawn as a strip (112), but can be any extended polygon along one or more edges of work piece as shown in FIGS. 3A and 3B.

As the source heats and melts the Si over layer (110) in contact with the initial planar seed (104), embedded in or adhered onto the seeding carrier, the molten silicon simultaneously undergoes a vertical out-of-plane and subsequent lateral in-plane seeding epitaxy of over layer (110). This epitaxy extends the crystal quality of the seed (104) to strip (112) of the over layer (110) and is the first step of the 2-D CZ ZMR method of this patent. And moreover, this re-crystallized region (112) becomes an intermediate seed of length “W” and width “Δε₁” along a complete dimension of the intended final work piece with overall dimensions of “L” by “W”.

In the second step of 2-D. CZ ZMR, a second heat source re-melts portions of the intermediate seed (112) that are in contact with the Si over layer (110) and that have not undergone re-crystallization. The second heat source is a heat source that has a lateral extent that is different than that of the first heat source with lateral extent Δε₁, according to certain embodiments. According to certain embodiments has a heat source with a lateral extent that is greater than the width “W” of the final work piece (114). Using smaller source size will result in lower quality process in re-crystallization. It is noteworthy to point out that ZMR can be implemented without a seeding strategy in a multi scan direction approach, but large populations of point defects and small grain growth will ensue forming large area poly silicon. Next, the molten intermediate seed promotes lateral epitaxy into new molten regions of over layer (110) as the second source scan direction begins and passes over the work piece (114) moving through the full scan dimension “L”. In this manner, the intermediate seed is replicated in the remainder of the Si over layer converting the entire low quality material into a single crystal film of arbitrary area “L” by “W”. Although Cartesian coordinates were used to describe a multi direction 2D CZ ZMR process, this art is not limited to and can be extended to other work piece geometry. According to certain embodiments, scan speeds of source or seeding carrier for first and subsequent source scans fall in the range of 0.001 mm/sec to 100 cm/sec.

Certain embodiments can include the use of a combination of a closed loop scanning heat source with real time feedback based on crystal quality during the melt, in a multi-directional scanning strategy to accomplish a novel form of zone melt and re-crystallization that allows arbitrary size areas to be re-crystallized using a planar Si seeding carrier. Classic zone melt re-crystallization or ZMR was first investigated in the 1970's al MIT for the purpose of melting and re-crystallizing films to form silicon on insulator technology (“SOI”). A more recent description of the technique can be found in Microelectronics Journal 37 (2006) pages 257-261.

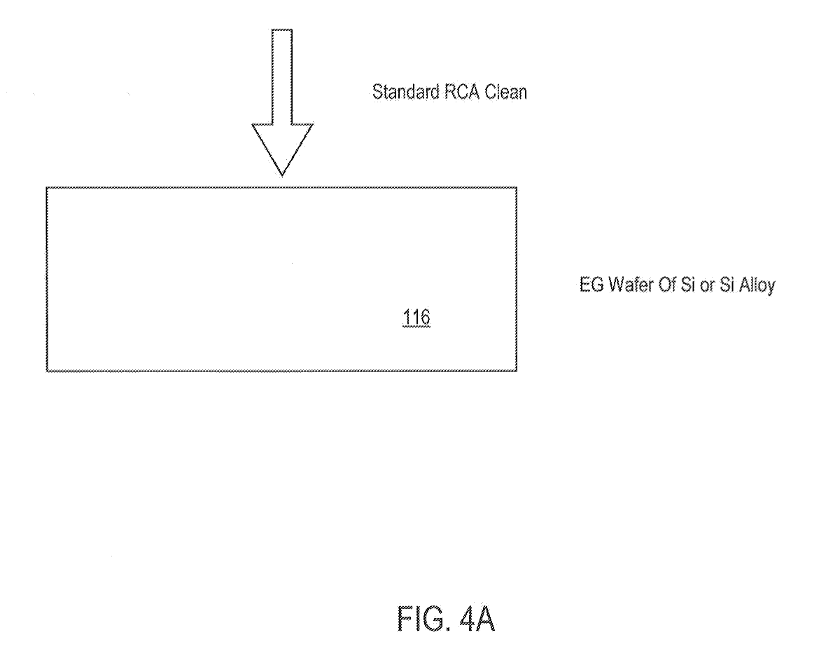

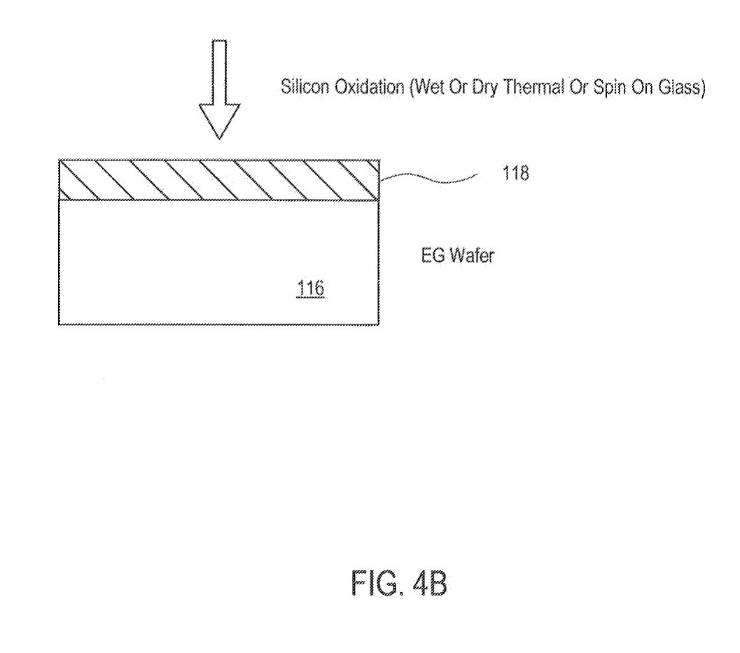

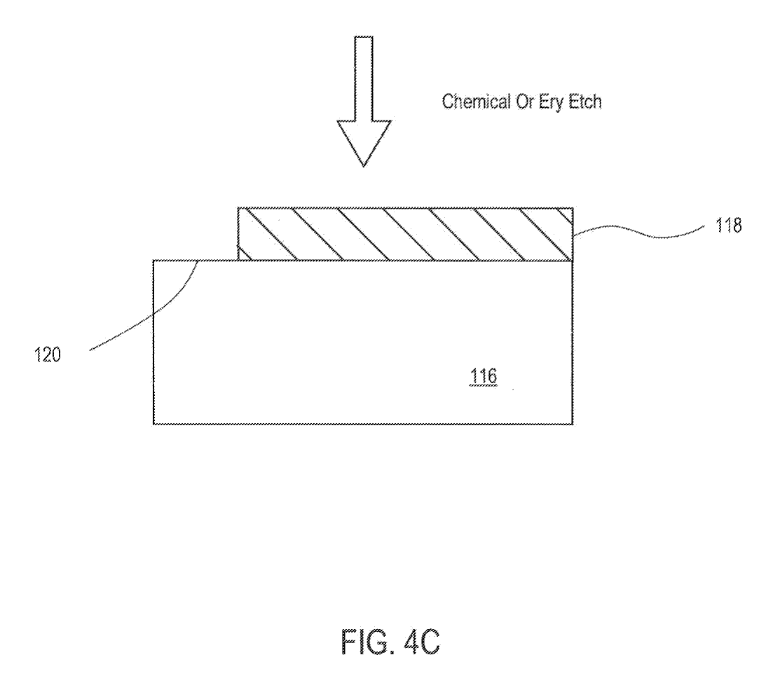

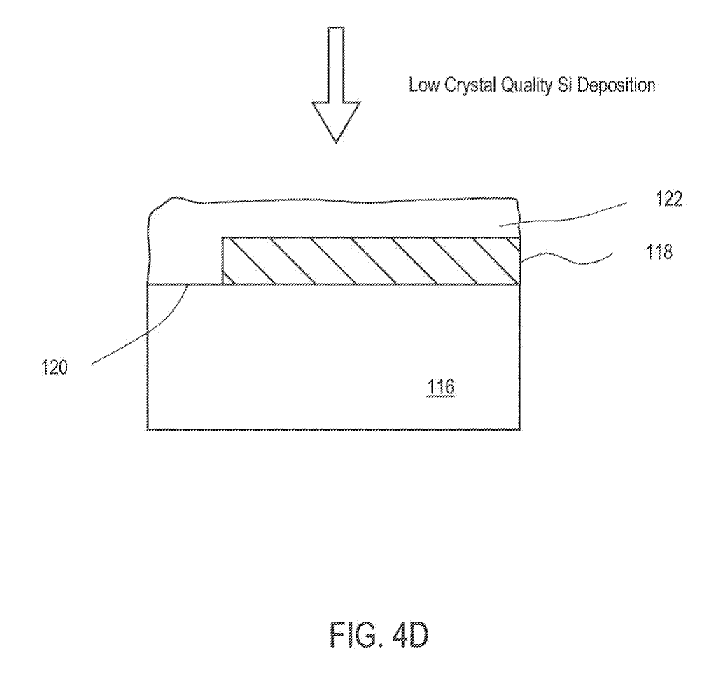

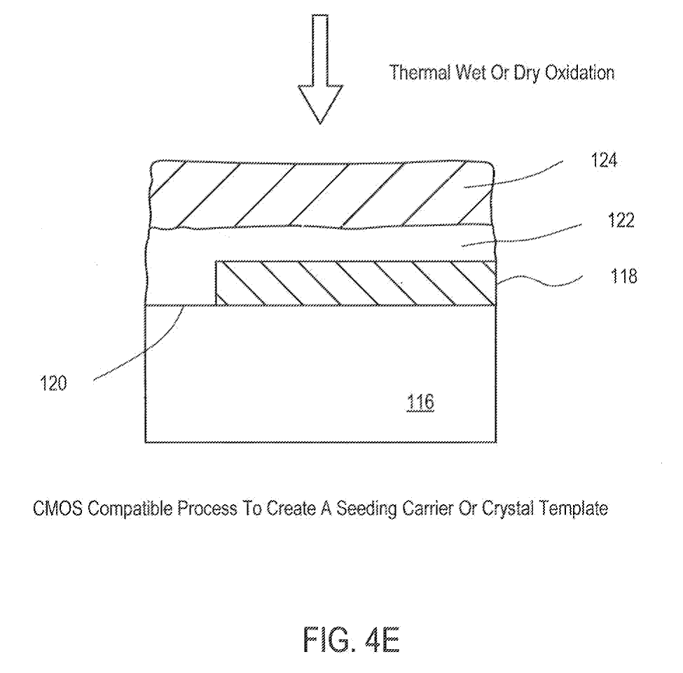

In a first embodiment, the seeding carrier (116) is formed by, but not limited to, a proposed CMOS compatible process shown in FIG. 4. In this case, a seeding carrier is produced from an electronic grade (EG) p-type Si (100) wafer, where the diameter and thickness can be any commercially available standard size according to certain embodiments. This wafer is reusable and is coated with a chemical silicon dioxide over layer (118) in the range, but not limited to, 1 to 3 microns in thickness, according to certain embodiments. According to other embodiments, the silicon dioxide over layer can have a thickness that is greater than 0.5 microns. Next, a small portion of the silicon dioxide layer is removed using a standard silicon dioxide etch along one or more sides of the wafer leaving exposed a high quality hydrogen terminated c-Si surface (120) of the EG wafer, known as the planar Si seed of the type depicted in FIG. 1A. This final reusable wafer with an exposed planar seed is the seeding carrier for this process. The Si over layer (122) described above is then applied to this seeding wafer carrier, coating uniformly the entire surface and at a thickness of about 40-50 microns according to certain embodiments. According to other embodiments, the Si over layer can be of a thickness that is greater than 5 microns.

Next, a sacrificial silicon dioxide layer (124) is grown using a spin coating technique such as PSOG or alternatively following a standard thermal silicon dioxide process, according to certain embodiments. This silicon dioxide serves as both an optically transparent window for a laser line heat source and mechanical layer to hold the Si layer flat during the subsequent melting step. For state of the art 156 mm by 156 mm solar wafers, the dimension of the planar see is “Δε₁=L” in FIG. 3A, 3B. Hence the 2D CZ ZMR process reduces to only the first step of the process describe with reference to FIGS. 3A and 3B for the wafer embodiment under consideration.

According to certain embodiments, the 2D CZ ZMR system encompasses the following engineering design requirements, but is not limited to, a) a linear heat source, for example, a laser line source or scanning Gaussian beam with sufficient laser fluence to penetrate and melt the Si over layer in a linear line with a dimension for exposure of 500 μm in width by 200 mm in length, according to certain embodiments, b) laser light at a wavelength (color) with sufficient absorption strength in Si to melt the Si over layer, c) a feedback control to ensure a uniform melt zone is created and maintained during the full length of the scan (greater than 156 mm for this solar wafer case), d) energy exposure profile with FWHM width of 100 μm to 500 um in the case of a laser energy source, e) continuous wave or high repetition rate mode of operation for the laser system, f) a wafer stage heater supplying, sufficient heating power such that the seeding carrier temperature reaches a range of greater than 600C (in the range of about 1000C to 1200C, according to certain embodiments) prior to melting, g) a cooling stage following the 2D CZ ZMR exposure in the range greater than 600C to step down and minimize stress and dislocation density in the film, h) a specialized inert gas curtain environment to create a clean manufacturing & melting environment or an air evacuated environment, and i) a linear scanning stage, or alternatively scanning line source, with speeds in the range of 0.01 mm per sec or greater.

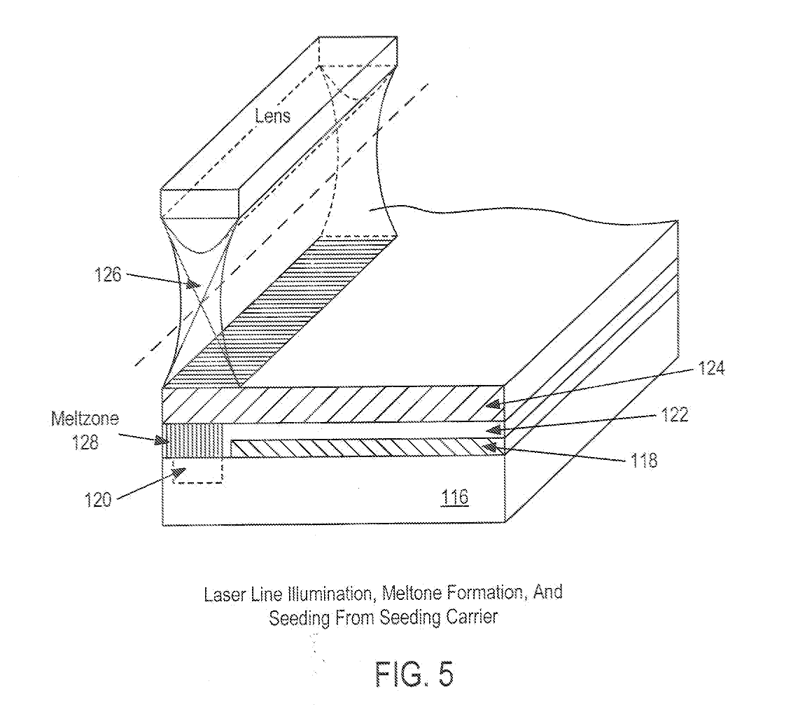

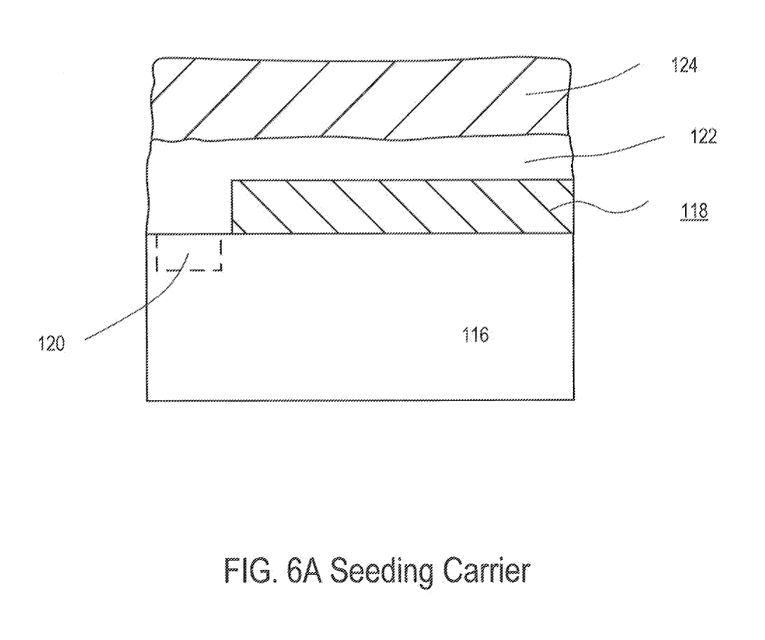

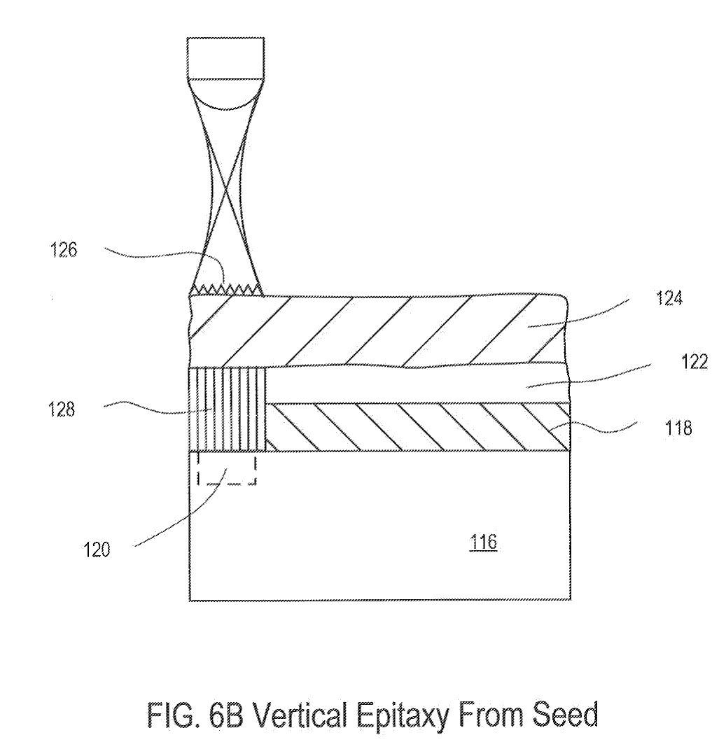

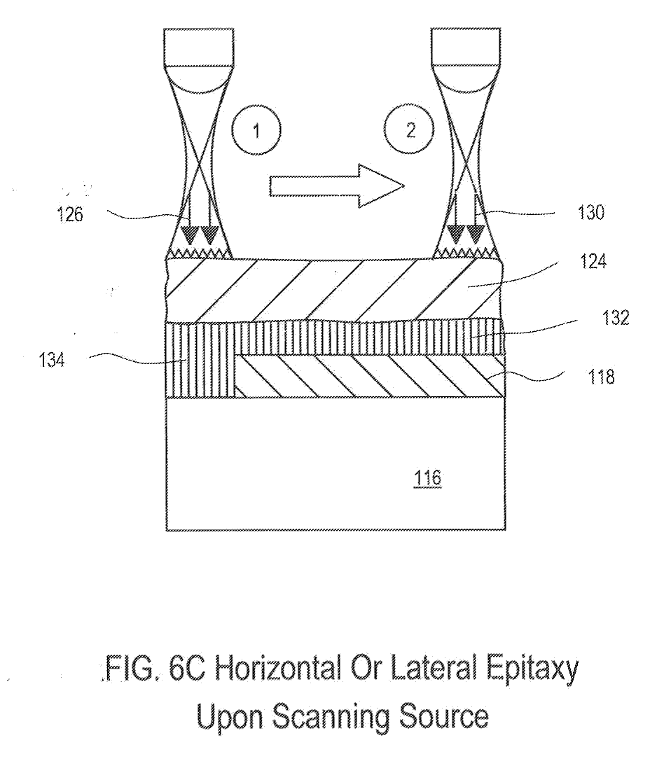

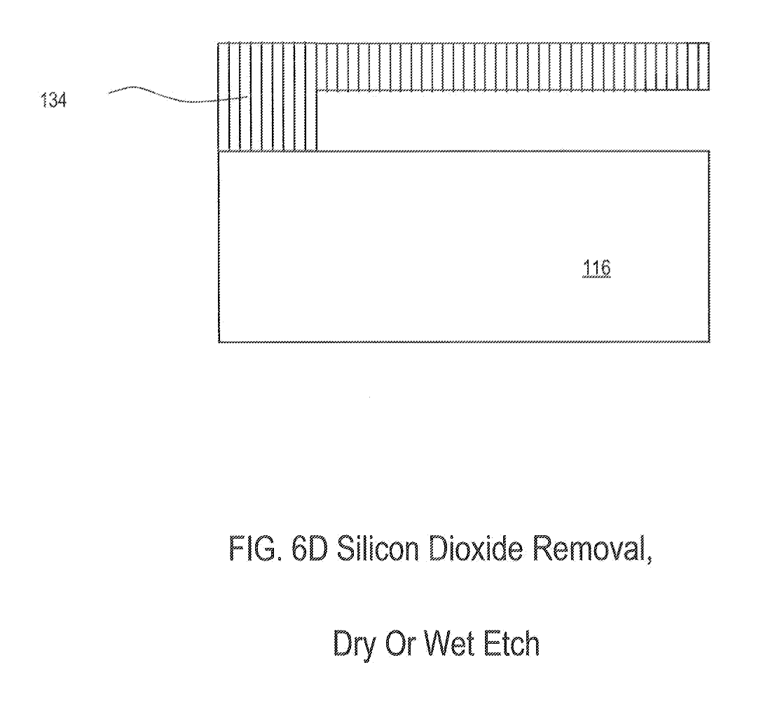

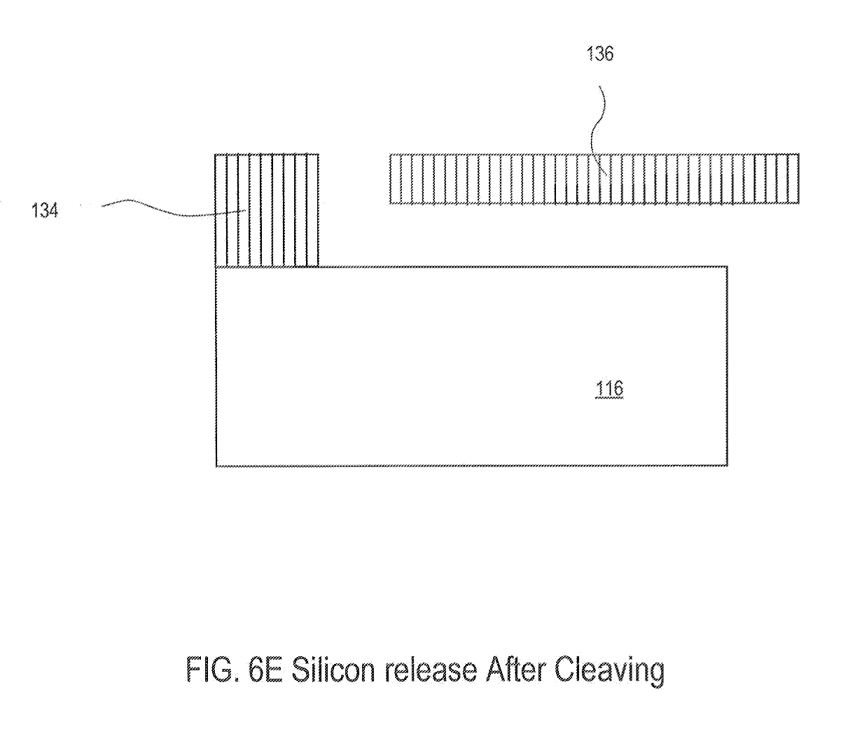

Next in FIG. 5, the seeding carrier (116) with silicon dioxide coating as a release layer (118), Si over layer (122) and Silicon dioxide window (124) is heated to a temperature greater than 600C, and the 2D CZ ZMR laser one source (126) is introduced over the Si seed (120) region. FIG. 5 shows the initial melt condition occurring in the region where the Si over layer (122) is in contact with the c-Si surface (120) acting as the seed of the seeding carrier (116). The laser fluence penetrates, and melts a rectangular column of the Si over layer (128) down to the c-Si seed (120), promoting the silicon seed to move initially vertically out of the plane of the wafer. This first step is called vertical Si over layer epitaxy. Secondly, as the laser line source (126) or the stage begins to scan in a direction that is orthogonal to the melt zone, in plane and horizontal Si over layer epitaxy ensues, according to certain embodiments. According to other embodiments, the laser line source (126) or the stage can scan in a direction that is greater than zero degrees but less than 180 degrees to the melt zone. The seeding is promoted from the c-Si interface vertically and is then pushed laterally by the linear scan of the laser-stage system. During the stage scan, a uniform melt zone is maintained through the full length of the laser line using active feedback control, with a closed loop locked into both temperature uniformity and crystal quality control according to certain embodiments. According to certain embodiments, a Si over layer (layer 122) takes, the seed from the seeding carrier (116) and results in replicating the single crystal through the entirety of the Si over layer through simultaneous seeding and ZMR re-crystallization. The re-crystallized single crystal Si layer is sandwiched between two silicon dioxide layers, the optical window (124) and a sacrificial release layer (118), all mechanically supported by the seeding carrier (116). FIG. 6A-E summarizes the complete process from seeding carrier formation through final wafer release step in producing a self standing film of c-Si following re-crystallization. FIG. 6A shows the seeding carrier with substrate (116), release layer (118), silicon seed (120) region, silicon over layer (122) and optical window (124). FIG. 6B depicts the vertical epitaxy step achieved by introducing the laser line heat source (126) and melting region (128), FIG. 6C is the horizontal epitaxy step-by moving the laser line source (126) over entirety of seeding carrier to its final position (130). The remaining re-crystallized film is shown in FIG. 6C as the c-Si film (134). Then, a silicon dioxide chemical removal step is employed in FIG. 6D to remove the silicon dioxide window (124) and the release layer (118) through chemical etching. After the silicon dioxide removal, FIG. 6D shows hydrogen terminated c-Si film (134) and all the film's surfaces are passivated for handling. Next the c-Si film is mechanically released as in FIG. 6E to form a self standing re-crystallized film that now exhibits single crystal mechanical and electronic properties. The c-Si film (134) is cleaved mechanically or by lasing scribing as shown in FIG. 6E. The released c-Si film (136) shown in FIG. 6E is the final outcome of the 2D CZ ZMR method, according to certain embodiments. Films produced in this manner replicate the single crystal quality of the underlying seeding carrier, and have typical recorded minority carrier lifetimes of >30 microsecs. The electronic properties of these self standing films if used as wafers for solar cell device fabrication, will lead to solar cell device efficiencies of >20% at the module level in production. These films can be used as direct replacements for sawn wafers derived from a east block or ingot, or CZ/FZ grown boule.

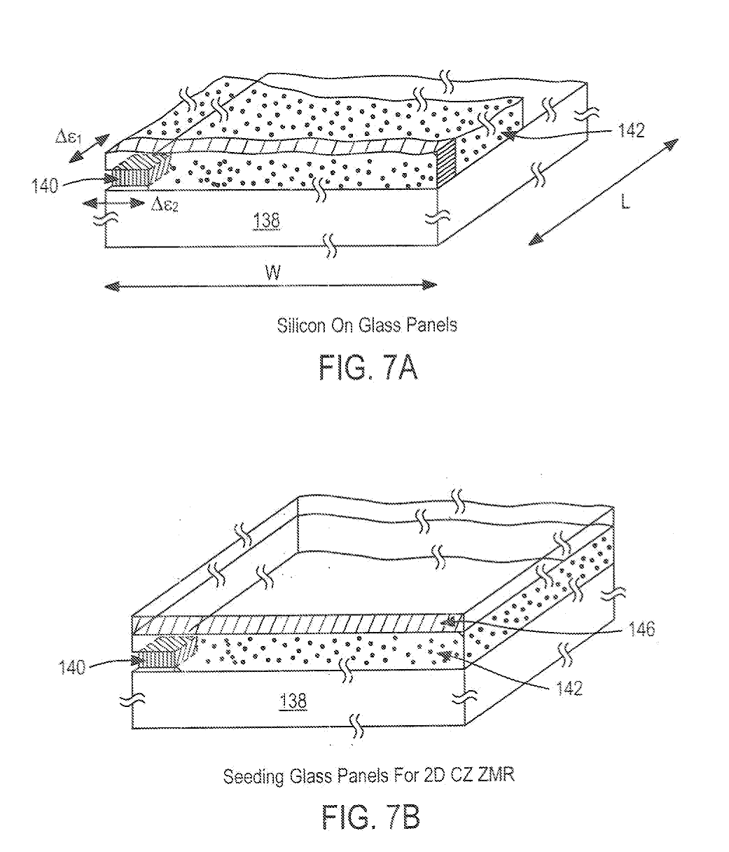

According to another embodiment, the 2D CZ ZMR method described herein with reference to FIG. 3A, 3B is applied to a high temperature glass panel to form a superstate. The outcome is a layer of c-Si adhered to an arbitrary large “L” by “W” work piece of transparent glass. FIG. 7A shows a high temperature glass substrate or panel (138), and a silicon seed (140) adhered to the surface of the glass work piece or panel. Next a low crystal quality Si over layer (142) is deposited over glass panel (138) covering the silicon seed (140), all of which is capped with a silicon dioxide layer (146) as shown in FIG. 7B. According to certain embodiments, a choice for the high temperature glass panel (138) includes, but is not limited to, a glass piece with a softening point that is greater than 1450 C. According to some embodiments, techniques for holding the Si seed (140) unto the large glass panel (138) in FIGS. 7A and 7B can include, but not limited to, anodic bonding, liquid spin on glass as an adhesive, liquid photo-resist as an adhesive, high temperature epoxies, mechanical placement followed by chemisorptions, and electrostatic adhesion. According to certain embodiments, upon adhering a single crystal piece of silicon with a thickness greater than 1 micron; either chemically, mechanically, or electrostatically onto the far edge of glass panel (138). According to certain embodiments, the single crystal piece of silicon can have a thickness of 30 to 50 microns. The large glass panel (138) is said to become a seeding carrier. In FIG. 7A, seeding carrier or glass panel (138) with Si seed (140) is coated with Si over layer (142). According to certain embodiments, the Si over layer (142) is 40 to 50 microns thick and uniformly coats the entire large surface area of glass panel. (138), typically greater than 0.5 meter by 0.5 meter in area. According to other embodiments, the/Si over layer (142) is greater than about 5 microns.

Next the 2D CZ ZMR method described herein with reference to FIG. 3A, 3B is followed to convert the Si over layer (142) into a single crystal c-Si film coating covering the entire glass panel (138). According to certain embodiments, the physical dimension of the laser line is 100 to 500 microns in width: by 25 mm to 200 mm in length for the first, step, sufficient to overfill the Si seed (140) along the Δε₁ dimension. And in the case of the second step, the laser line is 100 to 500 microns in width by “W” in length. As described before, the first step scans the source to form the intermediate seed (144) and propagates the seeding carrier crystal quality into this layer. Then the second step scans the source along the “L” direction and the intermediate seed is propagated horizontally and forms the final lateral epitaxy step of the 2D CZ ZMR method layer the arbitrarily large “L” by “W” glass panel (138). Again closed loop control maintains temperature uniformity across the melt zone and controls the speed of scans to obtain single crystal quality in this embodiment. Additionally we teach for large glass panels of type (138), a surface tension reduction gas curtain is required prior to scanning the heat source that melts Si layer (142). This gas curtain is characterized by a processing gas that flows above the surface of the Si over layer (142) as a driving force to cause the thermal silicon dioxide formation and reaction pathway to be highly inefficient during all high temperature steps in processing glass panel (138) using 2D CZ ZMR; heating and melting in the first step of scanning the source across “W”, and during the second step in scanning along the full length “L” of glass panel (138). The gas environment reduces the surface tension of the molten silicon to promote wetting and spreading anta the glass panel (138) surface once the Si over layer (142) becomes molten. This is a primary teaching because macroscopic surface tension will cause molten silicon lo ball up and not spread out like a film. According to certain embodiments, choices for the gas environment exposure include, but are not limited to, combinations of CO or CO₂, to dry O₂, or N₂ to NH₃ or various ratios of forming gas N₂:H₂. The ratio chosen for a given oxygen or nitrogen containing gas system dictates a gas filtration strategy that drives all chemical pathways or reactions allowing control of all unwanted chemical byproducts, and promoting spreading of the molten silicon during melt zone formation in Si over layer (142) during both steps of 2D CZ ZMR.

The resulting re-crystallized Si film (142) is 30 to 40 microns in thickness, according to certain embodiments and in direct contact with a transparent glass panel forming a superstrate. According to some other embodiments, resulting re-crystallized Si film (142) is greater than about 5 microns in thickness. This resulting thin film c-Si superstrate can be used for, but not limited to, solar panels, RFID chips, logic chips, memory; chips, large display technology, touch screens, and other silicon on insulator circuit applications. For example, an array of individual pn junctions can be fabricated in the c-Si layer (142) and interconnected by utilizing back side contact technology. Alternatively, a high temperature transparent conducting oxide (“TCO”) may be deposited as an intermediary layer between the high temperature glass panel (138) and the Si over layer (142) in FIGS. 7A and 7B. The latter allows traditional front side contacts, leasing only the pn junction formation and back side metallization contact step to complete an array of solar devices.

According to certain embodiments, a planar Si seeding strategy is proposed that enables the production of true single crystal silicon material in the form of thin self standing films or wafers and c-Si thin film on arbitrarily large pieces of glass panels. A primary teaching and advantage using 2D CZ ZMR, is the novel c-Si seeding strategy used in combination with uniform melt zone control by closing the loop on temperature uniformity of the melt zone. According to certain embodiments, the adaptation of an initial heat source scan orthogonal to (or at some non-zero angle to) a second heat source scan can form a new ZMR process that is a key enabler for large work pieces of arbitrary size to be re-crystallized. According to s=certain embodiments, the reaction environment is controlled to reduce the molten Si surface tension by tuning the ambient gas that promotes spreading and good adhesion to the substrate, which is known to be poor between molten Si and various forms of glass containing SiO₂. In this manner, the 2D CZ ZMR melting and re-crystallization method leads to film uniformity in thickness and grain size that is ≧0.5 meter in a given direction, leading to minority carrier lifetimes of >30 microseconds layer the entire glass panel and smooth topography over several square meters in area.

ZMR can be implemented without the planar Si seeds with a similar source scanning strategy, multi direction scan, but large populations of point defects and small grain growth will ensue.

A simple adaptation of adding multiple passes to either scan direction of the heat source can be added to adjust the heating profile of the zones being melted, according to certain embodiments.

According to certain embodiments, for large glass panels, the first scan can be repeated N times with a corresponding multitude of N planar Si seeds in the seeding carrier, and the low quality Si over layer can be deposited in rows via a shadow mask instead of a continuous film covering the N Si seeds. Then the repeated first scan can be stepped to new seed locations to generate N stripes of single crystal silicon over a large glass panel. This would remove the need to laser scribe the final work piece and making a natural means of producing N solar cells to be interconnected in series. This process can be extended in two dimensions to form an array of N by M seeds to form N×M patches to be manufactured into solar cells and connected in series.

Additionally, according to certain embodiments, doping layers can be deposited via an oxide cap of the silicon over layer to promote doping of the semiconductor during the 2D CZ ZMR heating process, such as doped spin on glass (such as PSG) to tailor the eleetrical] conductivity type of the resulting re-crystallized c-Si layer.

In the case of large glass panel work pieces, diffusion barrier layers, may be deposited prior to depositing the low quality Si over layer, according to certain embodiments. These layers may double as both diffusion barriers as well as wetting layers that promote spreading conditions for the molten silicon. The choices for this layer include, but are not limited to, Ti, various forms of SiC, various chemical forms of carbon; TaN, TiN, SiNₓ, and Nitrogen rich over layers that molten silicon forms a contact angle of less than 25 degrees, according to certain embodiments.

A simple adaptation is to use a high temperature optically opaque material in place of the high temperature glass panel, according to certain embodiments. After applying the 2D CZ ZMR method, the resulting substrate can be used for the purpose of fabricating the various semiconductor devices. The use of an intermediate seed produces single crystal Si on glass technology in an arbitrary aerial size forming a superstate for semiconductor devices employing transistor logic or memory, or PN junctions, and accompanying passive electronic components.

According to certain embodiments, “as-cut” poly-silicon wafers derived from standard cast silicon blocks, or CZ grown ingots, or other standard silicon growth techniques including ribbon growth can be upgraded in crystal quality through one or more source scans over a heated wafer resulting in monosilicon wafers.

According to certain embodiments, the following system can be used to implement the 2D CZ ZMR method as described above:
A shaped energy or heat source that is scanned in one or more directions in one or more passes per direction, and whose motion in the first to the subsequent scans is orthogonal or at other non-parallel angles in covering a multitude of exposure locations over a work piece known as a seeding carrier. The energy or heat sources include but are not limited to light beams, hot wire(s), focused lamp(s), fiber guided laser(s), optically, focused laser(s) in visible or non-visible wavelengths of the electromagnetic spectrum, focus charged particles including ions and electron beam(s), or pulsed electromagnetic radiation produced by waveguides and antennae. For example, the laser sources can be focused or guided by mirrors, lenses, light pipes, fiber optics, or gratings and can be of continuous wave or pulsed wave temporal characteristics, or a rastered pencil beam at sufficient high frequency to achieve a long extended energy deposition profile leading to a uniform melt zone in the silicon coated seeding carrier. For example, laser sources operate with typical power density characteristics of 50 Watts/cm or greater and at full width half maximum (FWHM) widths of 1.0 millimeter or less to melt the Si coating on the seeding carrier. According to certain embodiments, the shape of energy or heat source has an aerial shape of a block, or a narrow line, or a crescent moon, or an arrow head, or a circle, or an oval, or other polygon, or some combination of these shapes.
An active feedback hardware and closed loop control software to adjust the scan(s) speed(s) of the heat source with respect to a work piece that is a silicon coated seeding carrier. The feedback and closed loop control is used for improving the quality of melting and the resulting solidified crystal qualify of the re-crystallized silicon coating include temperature profiling using pyrometry in the imaging or non-imaging form, optical reflectivity from the surface of the molten silicon coating, contactless minority carrier lifetime and in situ conductivity methods using RF PCD, or microwave PCD, or eddy current probing, or other inductive coupled methods using transformers sensors, or RF bridge balancing techniques, or measuring the percentage of the reflected and transmitted power from the scanning heat source itself to detect molten state in spatial imaging or non-imaging modes, and physical thermal couples or thermystors.
A stage motion, or sample translation system, and or heat source translation system to apply a multi step and multi direction melting and re-crystallization strategy and simultaneous seeding process known as 2D CZ ZMR method.
A temperature adjustable stage or work piece holder to ramp up the silicon coated seeding carrier from room temperature to temperatures greater than 600 Celsius with active feedback or PID temperature control and capable of ramping back down to room temperature employing programmed logic control of cooling rates in 1 degree Celsius per minute accuracy, according to certain embodiments. Controlling the temperature cool down rate minimizes or completely removes dislocation densities in the re-crystallized Si layer.
A programmable flow controller manifold with a multitude of process gases (gas curtain) and flow rate control valves to achieve a gas chemical titration system during work piece heating, low crystal quality silicon layer melting and during re-crystallization. The gas process environment or chemical curtain is used to control and minimize unwanted chemical oxidation during the first and subsequent source scans during silicon melting and re-crystallization, and during heating and cooling of the seeding carrier prior to and after melting. The gas curtain is also used to reduce the Si liquid-vapor surface tension of molten silicon during the first and subsequent source scans by controlling the partial pressures of the chosen reaction gasses just above the seeding carrier surface and promote wetting layer large extended glass panels by molten silicon.
A conveyance system for moving work pieces in conjunction with scanning the heat sources.

1. A method for producing single crystal silicon, the method comprising:
coating an electronic or solar grade seeding carrier with silicon dioxide as a release layer;
depositing a layer of low crystalline quality silicon over a planar seed of high quality crystal silicon to form a silicon over layer; and
converting the silicon over layer into re-crystallized high crystalline quality silicon by melting the silicon over layer by scanning a shaped energy source over the silicon over layer in at least one direction.

2. The method of claim 1, further comprising:
removing a portion of the silicon dioxide to expose a portion of the electronic or solar grade wafer surface as the planar seed before depositing the silicon over layer; and
depositing a silicon dioxide optical window layer over the silicon over layer; and
removing the silicon dioxide optical window layer and the release layer after converting the silicon over layer into re-crystallized high crystalline quality silicon.

3. The method of claim 2, wherein converting the silicon over layer into re-crystallized high crystalline quality silicon includes:
using a shaped heat source to melt a portion of the silicon over layer, the portion being in contact with the planar seed to form a vertical silicon over layer epitaxy; and
scanning the shaped heat source in a direction orthogonal to or at a non-zero angle to the vertical silicon over layer epitaxy to form an in-plane and horizontal silicon over layer epitaxy.

4. The method of claim 2, wherein:
the coating of silicon dioxide release layer has a thickness in a range between 1 to 20 microns;
the silicon over layer has a thickness in the range between 40 to 50 microns; and
the shaped energy heat source is any one of:
a linear laser line source or a scanning Gaussian beam with a laser fluence and wavelength sufficient to penetrate and melt the silicon over layer;
a focus lamp;
a scanning ebeam;
a scanning ion;
a hot wire; and
a filament.

5. The method of claim 2, wherein:
the coating of silicon dioxide release layer has a thickness greater than about 0.5 microns;
the silicon over layer has a thickness greater than about 1 micron.

6. The method of claim 3, further comprising:
using a feedback control system based on a crystalline quality or melt temperature profile of the molten silicon over layer to create a uniform melt zone during a full length scan in the direction orthogonal to the vertical silicon over layer epitaxy when using the shaped heat source.

7. The method of claim 3, further comprising:
using seeding carrier heater to heat the seeding carrier to greater than 600C before melting the portion of the silicon over layer.

8. The method of claim 3, further comprising:
using seeding carrier heater to heat the seeding carrier to a range of from about 1000C to 1200C before melting the portion of the silicon over layer.

9. The method of claim 3, further comprising:
using an inert gas curtain or an air evacuated environment to create a clean manufacturing and melting environment by controlling and minimizing chemical oxidation during the melting of the first and second portions of the silicon over layer and re-crystallization of the silicon over layer into the re-crystallized high crystalline quality silicon.

10. The method of claim 3, wherein the shaped energy heat source:
is a laser source that has an exposure profile with a Full Width Half Maximum width greater than about 50 microns

11. The method of claim 3, wherein the shaped energy heat source:
is a laser source that has an exposure profile with a Full Width Half Maximum width in the range of about 100 microns to about 1 millimeter; and
is a continuous wave or operates at a high repetition mode of operation rate.

12. A method for producing single crystal silicon, the method comprising:
depositing a layer of low crystalline quality silicon over a high-temperature substrate that includes a planar seed to form a silicon over layer;
melting a first portion of the silicon over layer, the first portion being in contact with the planar seed, by scanning a first shaped energy source over the first portion of a silicon over layer in a first direction to form a first region of re-crystallized high crystalline quality silicon; and
melting a second portion of the silicon over layer, the second portion being in contact with the first region of re-crystallized high crystalline quality silicon by scanning a second shaped energy source over the second portion in a second direction to form a final region of re-crystallized high crystalline quality silicon.

13. The method of claim 12, further comprising:
adhering to a surface of or embedding into the high-temperature substrate the planar seed before depositing the low crystalline quality crystal silicon over layer over the planar seed; and
capping the low crystalline quality silicon over layer with a coating of silicon dioxide.

14. The method of claim 13, wherein:
the high-temperature substrate is a high-temperature glass panel substrate;
the planar seed has a thickness in the range of about 30 to 50 microns;
the silicon over layer has a thickness in the range of about 40 to 50 microns; and
the high-temperature substrate has a softening temperature greater than about 1550C and remaining solid when in contact with the molten silicon over layer.

15. The method of claim 13, wherein:
the planar seed has a thickness greater than about 1 micron;
the silicon over layer has a thickness greater than about 1 micron; and
the high-temperature substrate has a softening temperature greater than about 1420C and remaining solid when in contact with the molten silicon over layer.

16. The method of claim 13, wherein adhering is achieved by any one of chemical, mechanical and electrostatic adhesion onto a far-edge of the high-temperature substrate.

17. The method of claim 13, further comprising using a surface tension reduction gas curtain before melting the first portion of the silicon over layer, wherein the surface tension reduction gas curtain includes a processing gas that is flows above the surface of the silicon over layer to reduce surface tension of molten silicon over layer to increase wetting and spreading of the molten silicon over layer onto the high-temperature substrate.

18. The method of claim 17, further the processing gas can include any one of:
a combination of CO or CO2 with dry O2;
a combination of N2 with dry NH3; and
a combination of N2 to H2.

19. The method of claim 13, wherein scanning includes relative motion either linearly or rotationally of the one or more energy sources with respect to the high-temperature substrate.

20. The method of claim 9, further comprising:
using a feedback control system based on crystalline quality or melt temperature profile of the molten silicon over layer to create a uniform melt zone when melting the silicon over layer.

21. The method of claim 12, further comprising:
using a substrate heater to heat the high-temperature substrate to range greater than 600C before melting the portion of the silicon over layer.

22. The method of claim 12, further comprising:
using a substrate heater to heat the high-temperature substrate to range of about 1000C to 1200C before melting the portion of the silicon over layer.

23. The method of claim 13, further comprising:
depositing one or more diffusion barriers to the surface of the high-temperature substrate before adhering the planar seed and before depositing the silicon over layer over the planar seed.

24. The method of claim 12, further comprising:
using an inert gas curtain or an air evacuated environment to create a clean manufacturing and melting environment by controlling and minimizing chemical oxidation during the melting of the first and second portions of the silicon over layer and re-crystallization of the silicon over layer into the re-crystallized high crystalline quality silicon.

25. The method of claim 12, further comprising:
doping the silicon over layer using an oxide cap over the silicon over layer to tailor the electrical conductivity of the re-crystallized high crystalline quality silicon.

26. The method of claim 13, wherein the high-temperature substrate is any one of:
oxides of aluminum;
oxides of silicon;
oxynitrides;
silicon aluminum oxynitrides;
silicon carbides;
ceramics; and
mullite.

27. The method of claim 13, further comprising depositing a transparent conductive oxide layer before adhering the planar seed and before depositing the silicon over layer over the planar seed.

28. The method of claim 2, further comprising:
doping the silicon over layer using a boron or phosphors silicon dioxide cap over the silicon over layer to tailor the electrical conductivity of the re-crystallized high crystalline quality silicon before depositing the sacrificial silicon dioxide window layer.

29. The method of claim 2, wherein the silicon over layer comprises any one of or a combination of:
silicon that exhibits an amorphous grain structure; and
silicon with a polycrystalline grain structure.

30. The method of claim 12, wherein the silicon over layer comprises any one of or a combination of:
silicon that exhibits an amorphous grain structure; and
silicon with a polycrystalline grain structure.

31. The method of claim 12, wherein the first and second shaped energy heat sources:
is a laser source that has an exposure profile with a Full Width Half Maximum width in the range of about 100 microns to 1.0 millimeter; and
is a continuous wave or operates at a high repetition mode of operation rate.

32. The method of claim 12, wherein:
the first and second shaped energy heat source is any one of:
a linear laser line source or a scanning Gaussian beam with a laser fluence and wavelength sufficient to penetrate and melt the silicon over layer;
a focus lamp;
a scanning ebeam;
a scanning ion;
a hot wire; and
a filament.
